(19) United States
(12) Patent Application Publication
(10) Pub. No.: US 2026/0075729 A1
(43) Pub. Date: Mar. 12, 2026

(54) RACK LEVEL CAGE PHYSICAL SECURITY SYSTEM WITH MAGNETIC SENSOR SHIELD

(71) Applicant: Oracle International Corporation, Redwood Shores, CA (US)

(72) Inventors: Alexei Alexander Bulazel, New York, NY (US); Adam L. Reed, Middletown, RI (US); William Anthony Izzicupo, Bedford, NH (US)

(73) Assignee: Oracle International Corporation, Redwood Shores, CA (US)

(21) Appl. No.: 19/193,176

(22) Filed: Apr. 29, 2025

Related U.S. Application Data
(60) Provisional application No. 63/692,986, filed on Sep. 10, 2024.

(51) Int. Cl. H05K 5/02; H05K 5/03; H05K 7/14; H05K 7/18; H05K 9/00

(52) U.S. Cl. CPC H05K 5/0221; H05K 5/03; H05K 7/1491; H05K 7/18; H05K 9/0062

(57) ABSTRACT

A rack level cage physical security system with magnetic sensor shield is described herein. The rack level can be a physical security system that can include a rack cage, a body defining an internal volume that can contain at least one server, a door coupled to the body and moveable between an open position and a closed position, and a magnetic securement system that can prevent an external magnetic field from affecting a magnetic switch. The internal volume of the body can be accessible via the door when the door is in the open position.

### CROSS-REFERENCES TO RELATED APPLICATIONS

This application claims the benefit of U.S. Provisional Application Number 63/692,986, filed Sep. 10, 2024, and entitled Rack Level Cage, the entirety of which is hereby incorporated by reference herein.

### BACKGROUND

A server is a computer that provides information to other computers called “clients” on computer network. A server can provide various services including performing computations, sharing data, or the like.

A server can be a physical, bare-metal server, or can be a virtual server. Physical servers can be located in a server rack, which can provide physical support and protection for the servers. Servers in a server rack can be powered and can be interconnected with other computing components including other switches, or servers.

A server can be secured via physical or digital measures. Although measures are taken to secure servers, further improvements are desired.

### BRIEF SUMMARY

One general aspect of the present disclosure includes a physical security system. The physical security system can include a rack cage that can include at least one top opening. The system can also include a blocking plate secured to the rack cage to at least partially obstruct the top opening.

Implementations can include one or more of the following features. The blocking plate can allow cable to pass through the top opening and into the rack cage. The blocking plate can include an adjustable blocking plate. The adjustable blocking plate can include: a fixed member affixed to the rack cage; and at least one displaceable member.

The at least one displaceable member can be displaceable with respect to the fixed member. The fixed member can include at least one track portion. The at least one displaceable member can contact the at least one track portion. The at least one displaceable member can be moveably retained in the track portion such that the at least one displaceable member can slide along the track portion from a first position to a second position.

The fixed member further can include at least one adjustment feature. The at least one adjustable feature can include a plurality of first features that can mate with at least one corresponding second feature of the at least one displaceable member. The plurality of first features each can include a hole in the fixed member. The at least one second feature of the at least one displaceable member can include a protrusion. The protrusion can be sized to be received within the hole of at least one of the plurality of first features.

The physical security system can include a threaded member coupling the displaceable member to the fixed member. The at least one displaceable member can engage with the at least one adjustment feature to secure the at least one displaceable member in a desired position. The at least one displaceable member can be moveably retained in the track portion via at least one bottom track member and at least one top track member. The at least one bottom track member can be coupled to the at least one top track member.

The at least one displaceable member can include a first displaceable member and a second displaceable member. The first displaceable member can be located at a first end of the blocking plate and the second displaceable member can be located at a second end of the blocking plate.

The physical security system can include a server rack contained within the rack cage. The rack cage can include at least one of: one or more slots; one or more horizontal or vertical mounting rails; a built-in cooling mechanism; a built-in power supply; a built-in power distribution unit; or a cable organizer. The blocking plate can include a first end can include a step and a second end can include a plurality of tabs. The plurality of tabs can include a first set of tabs arranged on a first plane and a second set of tabs arranged on a second plane. The second plane can be positioned below the first plane.

One general aspect of the present disclosure relates to a physical security system. The physical security system can include a rack cage. The system can include a body defining an internal volume that can contain at least one server. The system can include a door coupled to the body and moveable between an open position and a closed position. The internal volume of the body can be accessible via the door when the door is in the open position. The system can also include a magnetic securement system that can prevent an external magnetic field from affecting a magnetic switch.

Implementations can include one or more of the following features. In some embodiments, the magnetic securement system can include a magnet; a magnetic switch; and a magnetic shield. The magnet can be coupled to the door. The magnetic switch can be coupled to the body. The magnetic shield can be coupled to the body and can be positioned to at least partially surround the magnetic switch. The magnetic shield can include a ferrous material. The magnetic switch can include a plurality of switch sides and a switch face. The switch face can be positioned proximate to the magnet when the door is in the closed position. The magnetic shield can include a shield wall. The shield wall can extend around the switch sides of the magnetic switch. The magnetic shield does not extend across the switch face such that the magnetic shield is not positioned between the magnetic switch and the magnet when the door is in the closed position.

One general aspect relates to a physical security system. The physical security system can include a rack cage. The system can include a body defining an internal volume that can contain at least one server. The system can include a door coupled to the body and moveable between an open position and a closed position. The internal volume of the body can be accessible via the door when the door is in the open position. The magnetic securement system can include: a magnetic switch, and a magnetic shield extending around a plurality of sides of the magnetic switch.

Implementations can include one or more of the following features. The physical security system in which the magnetic securement system can further include a magnet. The magnet can be coupled to the door. The magnetic switch can be coupled to the body. The magnetic shield can be coupled to the body and can be positioned to extend at least partially into a gap between the body and the door. The magnetic shield can be a ferrous material. The magnetic switch can include a plurality of switch sides and a switch face. The switch face can be positioned proximate to the magnet when the door is in the closed position. The magnetic shield can include a shield wall. The shield wall can extend around the switch sides of the magnetic switch. The magnetic shield does not extend across the switch face such that the magnetic shield is not positioned between the magnetic switch and the magnet when the door is in the closed position.

### BRIEF DESCRIPTION OF THE DRAWINGS

FIG. 1 is a perspective view of one embodiment of a rack level server.

FIG. 2 is a top view of one embodiment of the rack level server.

FIG. 3 is a top view of one embodiment of the rack level server with blocking plates.

FIG. 4 is a top perspective view of one embodiment of the blocking plate.

FIG. 5 is a bottom view of one embodiment of the blocking plate.

FIG. 6 is a side view of one embodiment of the blocking plate.

FIG. 7 is a perspective view of another embodiment of the rack level server.

FIG. 8 is a perspective view of the top of the other embodiment of the rack level server with blocking plates.

FIG. 9 is a front perspective view of a first embodiment of the blocking plate for the other rack level server.

FIG. 10 is a rear perspective view of the first embodiment of the blocking plate for the other rack level server.

FIG. 11 is a rear view of the first embodiment of the blocking plate for the other rack level server.

FIG. 12 is a side view of the first embodiment of the blocking plate for the other rack level server.

FIG. 13 is a rear perspective view of a second embodiment of the blocking plate for the other rack level server.

FIG. 14 is a front perspective view of a second embodiment of the blocking plate for the other rack level server.

FIG. 15 is a side view of a second embodiment of the blocking plate for the other rack level server.

FIG. 16 is a rear perspective view of a third embodiment of the blocking plate for the other rack level server.

FIG. 17 is a front perspective view of a third embodiment of the blocking plate for the other rack level server.

FIG. 18 is a side view of a third embodiment of the blocking plate for the other rack level server.

FIG. 19 is a top view of a portion of the rack level cage.

FIG. 20 is a perspective view of a magnetic securement system.

FIG. 21 is a perspective view of a magnetic securement system with shield wall comprising separate wall segments.

### DETAILED DESCRIPTION

A server is a computer that provides information to other computers called “clients” on computer network. A server can provide various services including performing computations, sharing data, or the like.

A server can be a physical, bare-metal server, or can be a virtual server. Physical servers can be located in a server rack, which can provide physical support and protection for the servers. Servers in a server rack can be powered and can be interconnected with other computing components including other switches, or servers.

Physical access to servers is tightly controlled because physical access to any computer system is tantamount to logical control. Unauthorized physical access can be prevented by enforcing myriad security controls and contractual mandates. These security controls can include requirements for fencing around a facility containing one or more servers, cameras, security guards, access control systems, or the like.

Thus, great effort has been made to protect servers from malicious actors. However, in the event that a malicious actor gains access to a room, facility and/or location containing one or more servers, the actor may be able to physically access the server to, for example, alter the connections of one or several servers, to remove one or more hard drives, to access one or more server ports, or the like. Additionally, one or more servers may be placed in a physical location to which external operators or personnel may have access. In such situations, the one or more servers themselves should be secured.

For example, in some embodiments, a multicloud strategy can be implemented, which multicloud strategy can utilize services from multiple cloud providers to deploy a solution. In such an embodiment, servers from multiple providers may be provided in a single geographic location. Due to the shared geographic location, actors from the different cloud providers may access this common location, thereby degrading security. Alternatively, in some embodiments, a cloud provider may place one or more servers in a customer's on-premise environment. Again, this embodiment may result in undesired actors having access to this location, thereby degrading security.

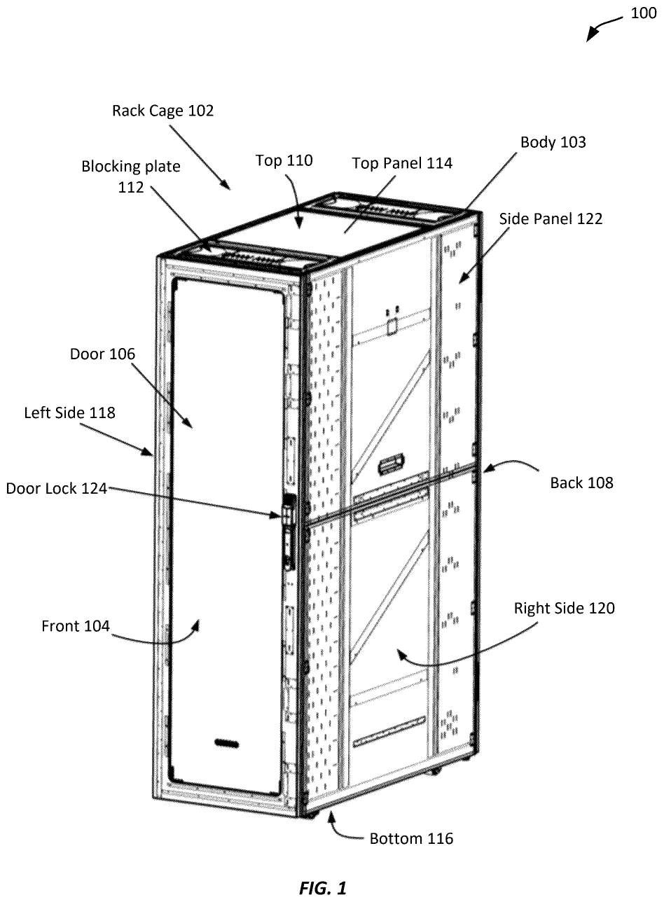

The present relates to systems, methods, and devices to provide physical security to a server. One embodiment of a system 100 is shown in FIG. 1.

The system 100 can include a rack cage 102 comprising a body 103. The rack level cage 102 and/or the body 103 can define an internal volume that can be configured to contain at least one server. The rack cage 102 includes a front 104 having a door 106, and opposing back 108, a top 110 including one or more blocking plates 112 and/or a one or more top panels 114, an opposing bottom 116, a left side 118, and a right side 120, each of the sides including one or more side panels 122. The door 106 can be moveable between an open position and a closed position, and can include a door lock 124 that can be an electronic door lock. In some embodiments, the internal volume of the rack cage 102 and/or the body 103 is accessible via the door 106 when the door 106 is in the open position.

In some embodiments, one or more server racks, switches, and/or the like can be contained within the rack level cage 102. In some embodiments, the rack level cage 102 can comprise one or more slots, one or more horizontal and/or vertical mounting rails, a built-in cooling mechanism, a built-in power supply, a built-in power distribution unit, a cable organizer, and/or the like.

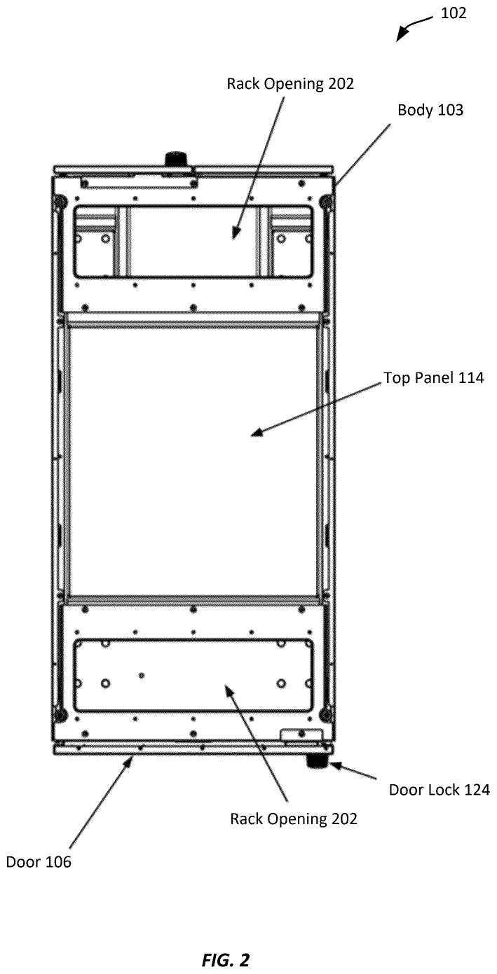

A top view of the rack cage 102 is shown in FIG. 2. As seen, the body 103 includes at least one top rack openings 202. Although depicted as located in the top 110 of the body 103, the rack openings 202 can be located at any position on the rack 102. In some embodiments, the rack opening 202 can be provided to allow access to one or more servers contained in the rack 102 and/or to allow cables to pass into or out of the rack 102.

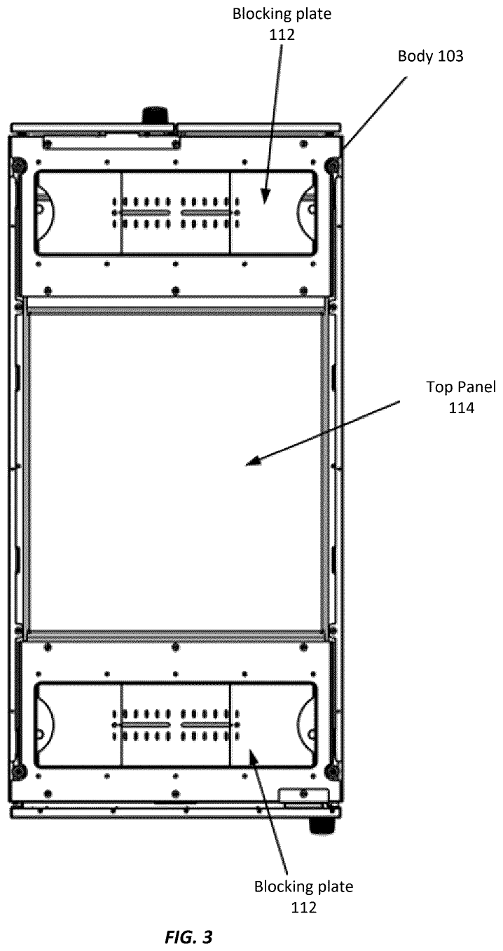

In some embodiments, the system 100 can include one or more blocking plates 112. The one or more blocking plates 112 can be secured to the rack cage 102 to at least partially obstruct at least one opening 202. The blocking plates 112 can, as depicted in the top view of the system 100 shown in FIG. 3, obstruct all or portions of some or all of the rack openings 202, and specifically, as depicted, can obstruct all or portions of the top rack openings 202. In some embodiments, the blocking plates 112 can comprise a single member, or, as depicted below, can comprise multiple components. In some embodiments in which the blocking plates 112 can comprise multiple components, these components can be adjusted with respect to each other to allow some access to the body 103 via the partially obstructed rack openings 202, or in other words to selectably obstruct all or portions of the rack openings 202. In some embodiments, this can allow cables to pass the blocking plate 112 while minimizing access through the rack openings 202. In such an embodiment, the blocking plates 112 can be configured to allow access through the rack openings 202 while preventing other access through the rack openings 202. Thus, in some embodiments, the blocking plate 112 can be configured to allow a cable to pass through the opening 202 in the rack cage 102.

The blocking plate 112 can comprise a variety of shapes and sizes and can be made from a variety of materials. In some embodiments, the blocking plate 112 can comprise an adjustable blocking plate or a non-adjustable blocking plate. The blocking plate 112 can, in some embodiments, comprise one or more metal sheets have one or more desires thicknesses, strengths, shapes, or the like. In some embodiments, the metal can comprise, for example, steel, aluminum, or the like. In some embodiments, all or portions of the blocking plate 112 can comprise a non-metallic material such as, for example, polymer including plastic, composite, or the like.

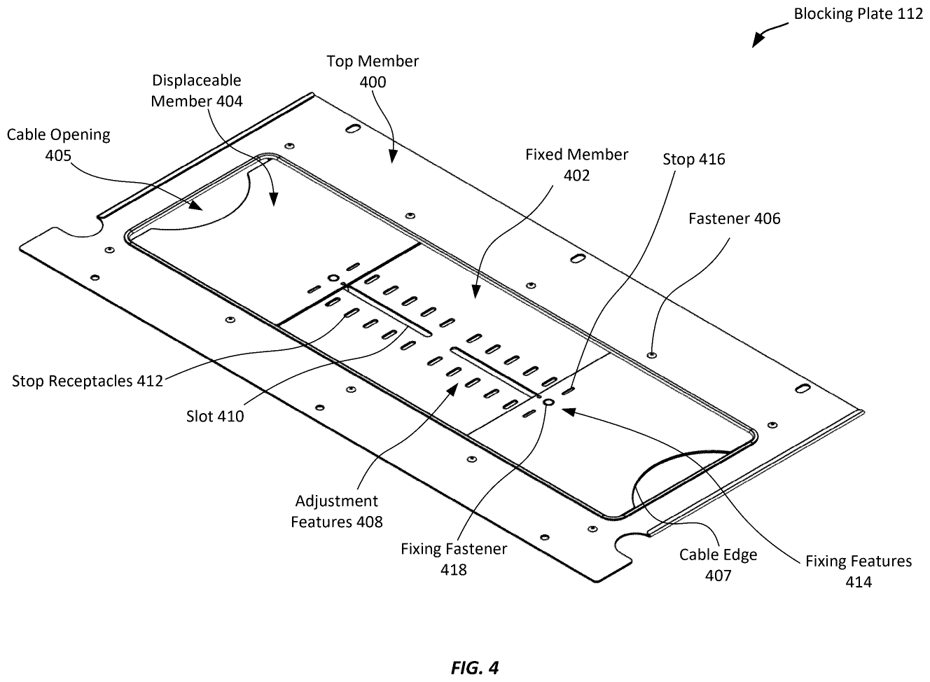

In some embodiments, and as depicted in FIG. 4, the blocking plate 112 can include a top member 400, a fixed member 402, and one or more adjustable members 404, also referred to herein as displaceable members 404. In some embodiments, and as shown in FIG. 4, the blocking plate 112 can include two displaceable members 404 both of which are coupled to the fixed member 402. In some embodiments, and as shown in FIG. 4, the first displaceable member 404 is located at a first end of the blocking plate 112 and the second displaceable member is located at an opposite, second end of the blocking plate 112.

In some embodiments, the top member 400 can be affixed to the rack cage 102, and in some embodiments, can be affixed to the top panel 114 of the rack level cage 102. In some embodiments, the adjustable members 404 can be positioned with respect to the fixed member 402 to thereby control the size of a cable opening 405 in the rack cage 102. Advantageously, this can allow for the secure passing of different numbers and/or sizes of cables through the cable opening 405 and into the rack cage 102.

In some embodiments, the displaceable member 404 can comprise a cable edge 407. The cable edge 407 can comprise a concave shaped portion configured to facilitate in creating the cable opening 405 through which cables can pass when the displaceable member 404 is fully advanced to minimize the cable opening 405. In some embodiments, the cable edge 407 can be configured to be pressed into one or more cables without damaging or severing the cables. This can include, for example, the cable edge 407 being rounded, chamfered, folded, having a double thickness, or the like.

The fixed member 402 can be affixed, either directly or indirectly to the rack cage 102. The fixed member 402 can, in some embodiments be secured to top member 400 via, for example, one or several fasteners 406 including one or several rivets, screws, bolts, or the like. The fixed member 402 can be made from a variety of materials in a variety of dimensions. In some embodiments, the fixed member 402 can comprise sheet metal such as steel sheet metal having a thickness between 1 mm and 3 mm, and in some embodiments having a thickness of approximately 1.2 mm. In some embodiments, the steel can comprise a cold-rolled steel.

The fixed member 402 can include one or more adjustment features 408. These adjustment features 408 can include, for example, one or more slots 410 and one or more stops 412. In some embodiments, each of the one or more slots 410 can comprise a thru-hole extending through the fixed member 402. In some embodiments, each of the stop receptacles 412 can define a volume configured to receive a stop 416. In some embodiments, the each of the stop receptacles 412 can comprise a thru-hole extending through the fixed member 402, and in some embodiments, each of the stop receptacles 412 can comprise a depression configured to define a volume configured to receive a stop 416, which stop can, in some embodiments, comprise a protrusion that can be sized to be received within each of the stop receptacles 412.

The displaceable member 404 can be made from a variety of materials in a variety of dimensions. In some embodiments, the displaceable member 404 can comprise sheet metal such as steel sheet metal having a thickness between 0.5 mm and 3 mm, and in some embodiments having a thickness of approximately 1 mm. In some embodiments, the steel can comprise a cold-rolled steel.

The displaceable member 404 can include one or more fixing features 414 that can be configured to, together with the adjustment features 408 secure the position of the displaceable member 404 with respect to the fixed member 402. In some embodiments, these fixing features 414 can include, for example, a stop 416 and a fixing fastener 418 which can comprise a threaded member. In some embodiments, the stop 416 can comprise a feature extending above the surface of the displaceable member 404 and configured to be received within the stop receptacle 412. Although the stops 416 are described herein as being located on the displaceable member 404 and the stop receptacles 412 are described as being located on the fixed member 402, a person of skill in the art will recognize that the location of these features could be swapped.

In some embodiments, the one or more slots 410 can be configured to allow the fixing fastener 418, such as a bolt, coupled to the displaceable member 404 to pass through the slot 410. A mating member such as a nut can be coupled to the fixing fastener 414 to press the displaceable member 404 against the fixed member 402 to thereby locate the stops 416 inside of the stop receptacles 412. The location of the stops 416 inside of the stop receptacles 412 can securely fix the position of the displaceable member 404 by fixing the position of the displaceable member 404 with respect to the fixed member 402.

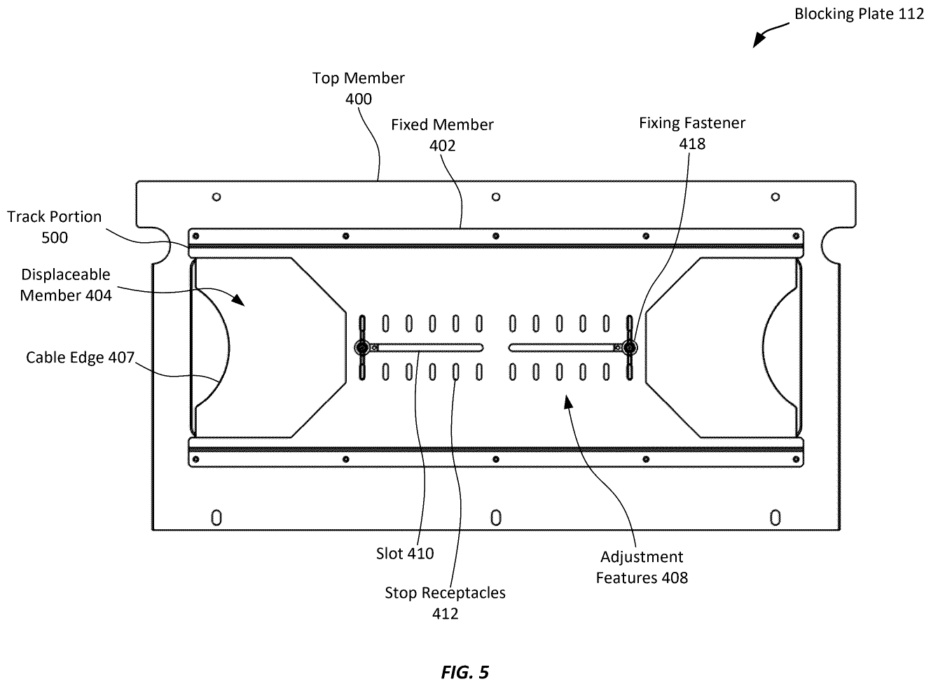

FIG. 5 depicts a bottom view of the of the blocking plate 112. As depicted, the fixed member 402 is affixed to the top member 400 so as to create a track portion 500. In some embodiments, the fixed member 402 alone or in combination with the top member 400 can comprise the track portion 500. The displaceable member 404 is positioned within the track portion 500 and/or contacts the track portion 500 such that the displaceable member 404 can slide parallel to the fixed member 402, but in some embodiments, cannot move perpendicular to the fixed member 402.

In some embodiments, the one or more displaceable members 404 can be moveably retained in the track portion 500 such that the one or more displaceable members 404 can be slide along the track portion 500 from a first position to one or more second positions. The one or more displaceable members 404 can engage with the one or more adjustment features 408 to secure the one or more displaceable members 404 in one or more desired positions. In some embodiments, and either alone or in combination with one or more of the adjustment features 404 the fixing fastener 418 such as a screw a bolt, or the like can selectably secure the displaceable members 404 in a desired position with respect to the fixed member 402.

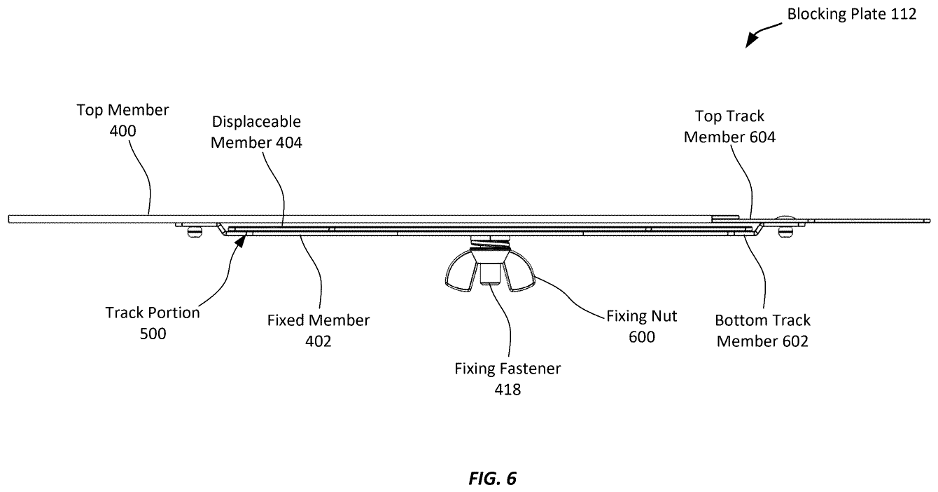

With reference now to FIG. 6, a side view of the blocking plate 112 is shown. As seen in FIG. 6, the displaceable member 404 is located within the track portion 500 such that the top member 400, and specifically a top track member 604 of the top member 400 extends at least partially above the displaceable member 404 and such that the fixed member 402, and specifically a bottom track member 602 of the fixed member 402 is located at least partially below the displaceable member 404. Via the positioning of the top track member 604 and the bottom track member 602, the track portion 500 prevents the movement of the displaceable member in a direction perpendicular to the fixed member 402. In some embodiments, the displaceable member 404 is moveably retained in the track portion 500 via at least the one bottom track member 602 and at the least one top track member 604. In some embodiments, the at least one bottom track member 602 is coupled to the at least one top track member 604.

As also seen in FIG. 6, the fixing nut 600 is coupled to the fixing fastener 418. In some embodiments, tightening of the fixing nut 600 on the fixing fastener 418 can compress the displaceable member 404 against the fixed member 402 such that the position of the displaceable member 404 is fixed with respect to the fixed member 402.

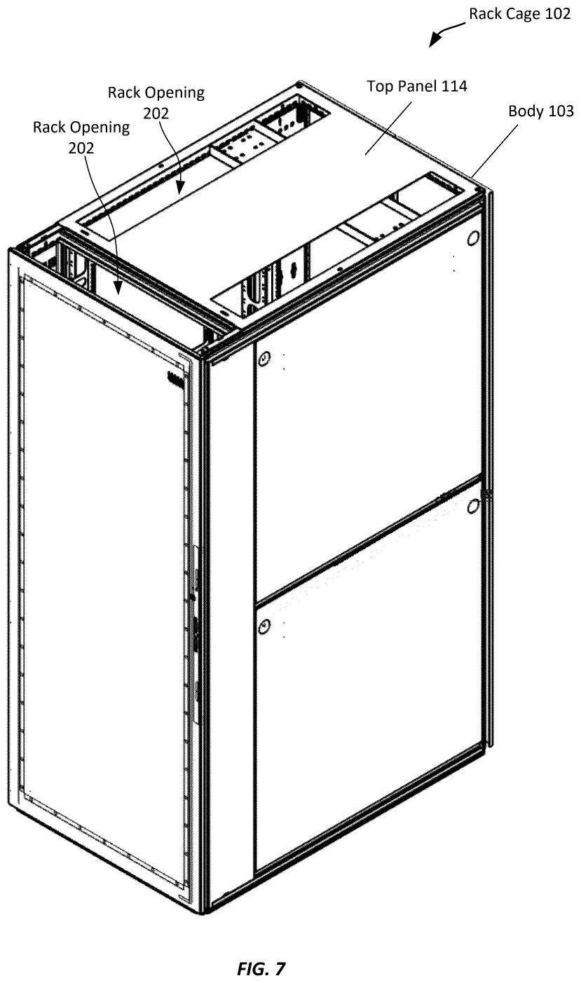

With reference now to FIG. 7 a perspective view of a second embodiment of the rack level cage 102. The rack level cage 102 includes the features of the rack level cage 102 previously described herein including a body 103 and a top panel 114. As depicted, the rack level cage 102 includes a plurality of rack openings 202 at different locations and having different sizes.

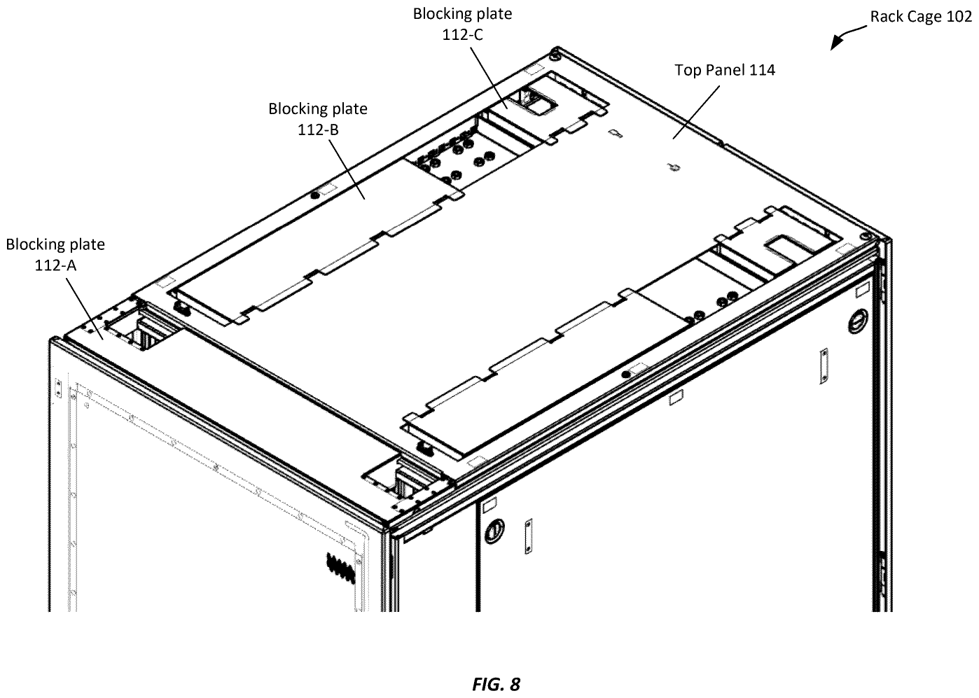

With reference now to FIG. 8, a perspective view of the second embodiment of the rack level cage 102 having a plurality of blocking plates 112 obstructing the rack openings 202. As seen in FIG. 8, the blocking plates 112 include a first blocking plate 112-A, a second blocking plate 112-B, and a third blocking plate 112-C.

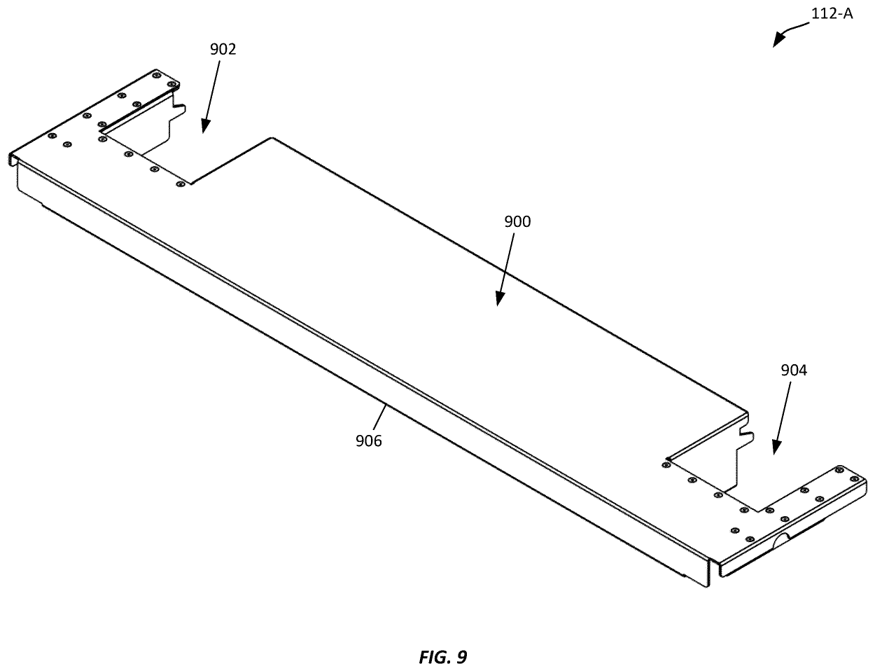

FIG. 9 depicts a front perspective view of the first blocking plate 112-A. The first blocking plate 112-A can be configured to obstruct a rack opening 202 at the front of the top panel 114. The first blocking plate 112-A can comprise a plate top 900 defining a first opening 902 and a second opening 904. In some embodiments, both the first opening 902 and the second opening 904 can be sized to allow one or more cable to pass from within the rack level cage 102 to outside of the rack level cage 102. In some embodiments, these openings 902, 904 can be sized to allow passage of these cables from within the rack level cage 102 to outside of the rack level cage 102 without allowing undesired access of body parts and/or tools into portions of the rack level cage 102 containing sensitive components, equipment, and/or the like.

In some embodiments, and as depicted in FIG. 9, the first blocking plate 112-A can further include a front lip 906.

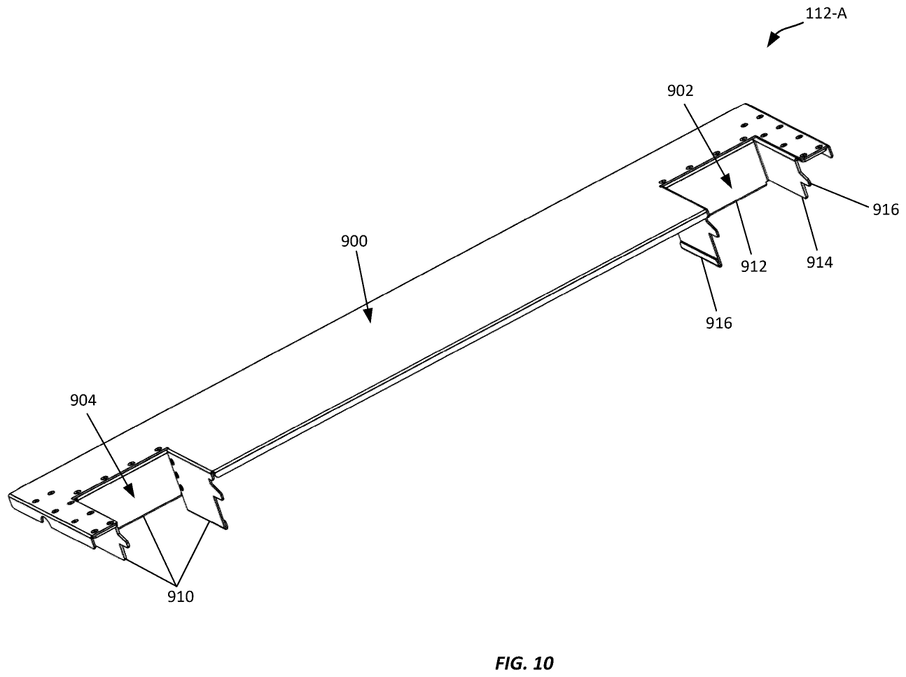

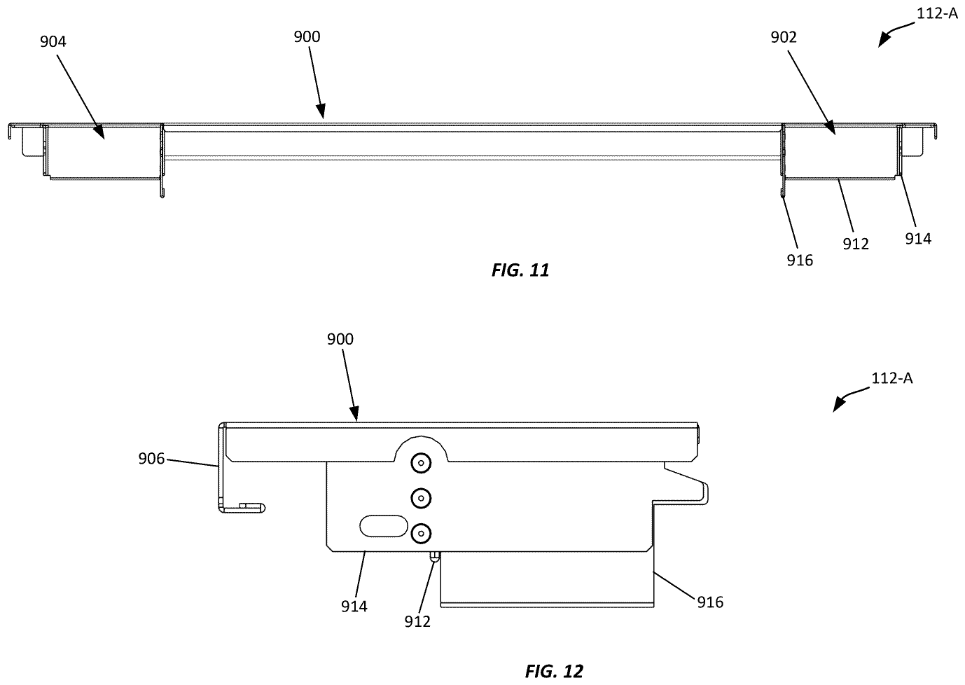

FIG. 10 depicts a back perspective view of the first blocking plate 112-A. As seen, each opening is further defined by opening walls 910 that extend downward from the plate top 900. These opening walls 910 include a front opening wall 912, an exterior opening wall 914, and an interior opening wall 916. As seen in FIG. 10, each of the interior opening wall 916 and the exterior opening wall 914 includes a tab configured to engage with the body 103 of the rack level cage 102. In some embodiments, each of the front opening wall 912, the interior opening wall 916, and the exterior opening wall 914 can have a height. In some embodiments, each of the front opening wall 912, the interior opening wall 916, and the exterior opening wall 914 can have the same height, or can have a different height. As further seen in FIG. 10, the interior opening wall 916 has a greater height than either the exterior opening wall 914 or the front opening wall 912. This difference in height of the opening walls 912, 914, 916 is further depicted in FIG. 11, a back view of the first blocking plate 112-A and in FIG. 12, a side view of the first blocking plate 112-A. Thus, as shown, the interior opening wall 916 extends further away from the plate top 900 than either the exterior opening wall 914 or the front opening wall 912. In some embodiments, the height of the opening walls 912, 914, 916 can be selected and/or configured to protection portions of the interior of the rack level cage 102.

In some embodiments, the interior opening wall 916 can be formed from the same sheet of metal as the top plate 900. In some embodiments, both the front opening wall 912 and the exterior opening wall 914 can be formed from one or more different sheets of metal, which can be coupled to the top plate 900 via, for example, one or more fasteners such as one or more rivets.

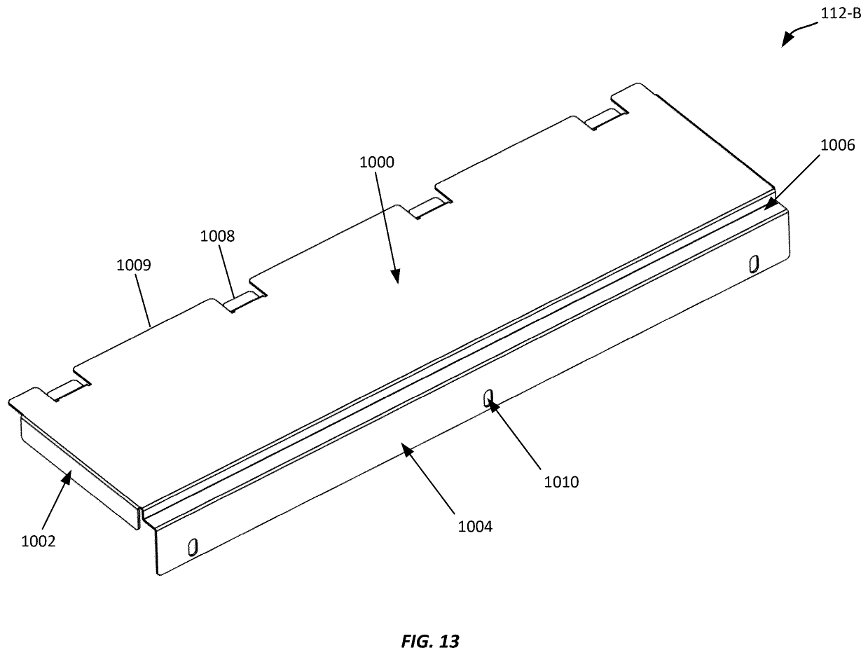

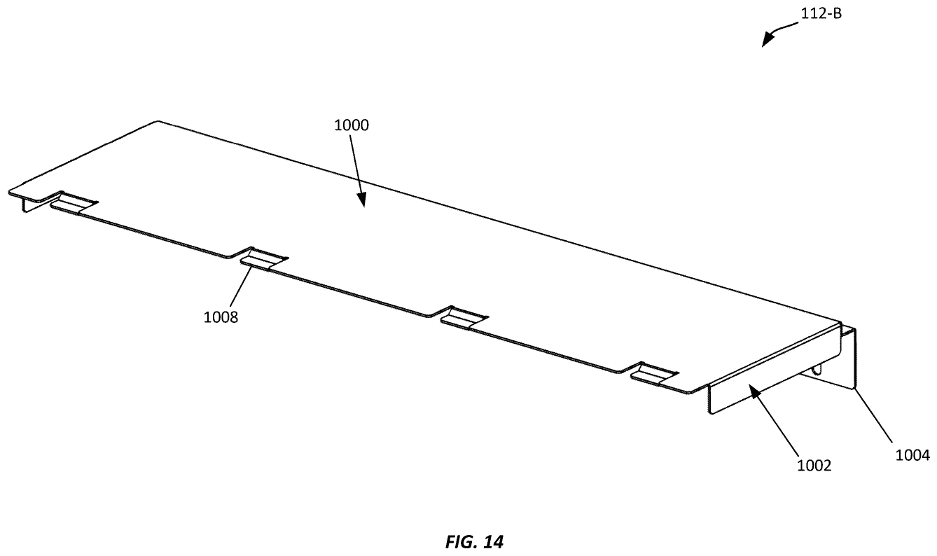

FIG. 13 is a rear perspective view of the second blocking plate 112-B, and FIG. 14 is a front perspective view of the second blocking plate 112-B. The second blocking plate 112-B can be configured to be received in one of the openings 202 in the rack level cage 102. The second blocking plate 112-B can comprise a top plate 1000, side plates 1002, a rear plate 1004, a step 1006 located between and connecting the rear plate 1004 to the top plate 1000, a plurality of depressed tabs 1008, and a plurality of planar tabs 1009. In some embodiments, the planar tabs 1009 can be located in a first plane, which can be the same plane as the top plate, and the depressed tabs 1008 can be located in a second plane below the plane of the planar tabs 1009. In some embodiments, the step 1006 can be configured to engage with a portion of the top panel 114 of the rack level cage 102. Thus, in some embodiments, the blocking plate 112-B can comprise a rear, also referred to herein as a first end comprising the step 1006 and a front, also referred to herein as the front comprising a plurality of tabs. In some embodiments, the second blocking plate 112-B can comprise four depressed tabs 1008.

The plurality of depressed tabs 1008 can, in combination with the top plate 1000, receive a portion of the top panel 114. In some embodiments, the portion of the top panel 114 can be received between the depressed tabs 1008 and the top plate 1000 and the second blocking plate 112-B can be moved such that the step 1006 engages with the top plate, at which point one or more fasteners can secure the rear plate 1004 to the rack level cage 102. In some embodiments, the one or more fasteners can secure the rear plate 1004 to the rack level cage 102 via one or more apertures 1010 in the rear plate 1004.

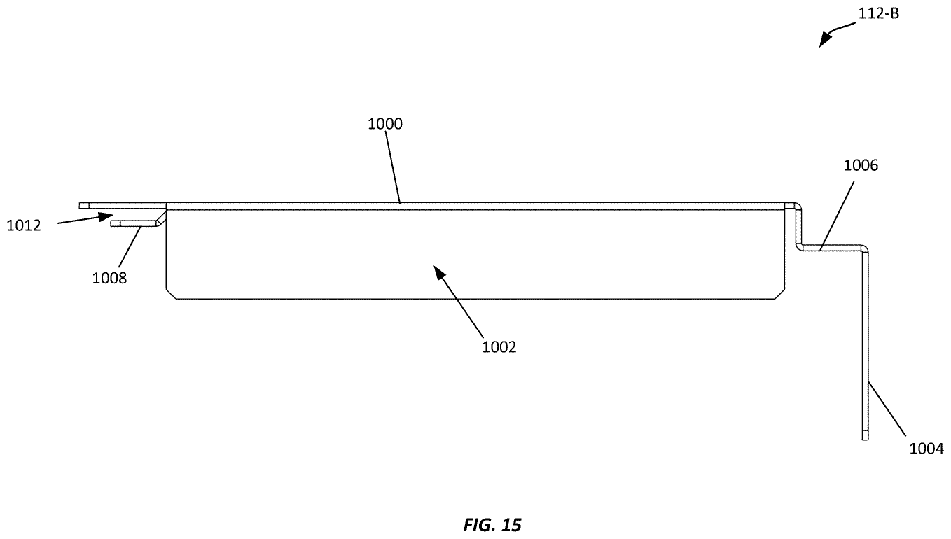

FIG. 15 is a side view of the second blocking plate 112-B. As seen, the depressed tabs 1008 are at a level below the top plate 1000, thereby defining a receiving volume 1012 in which the top panel 114 can be received.

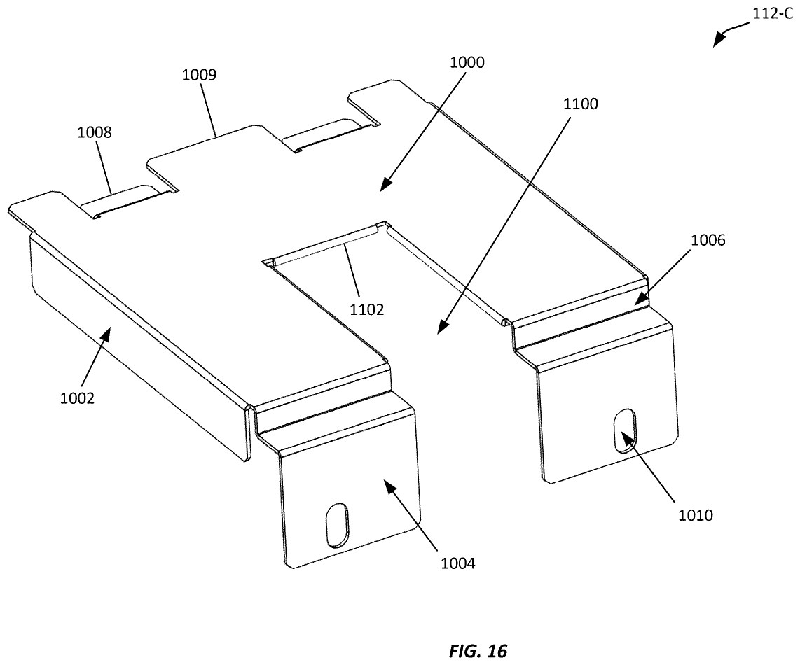

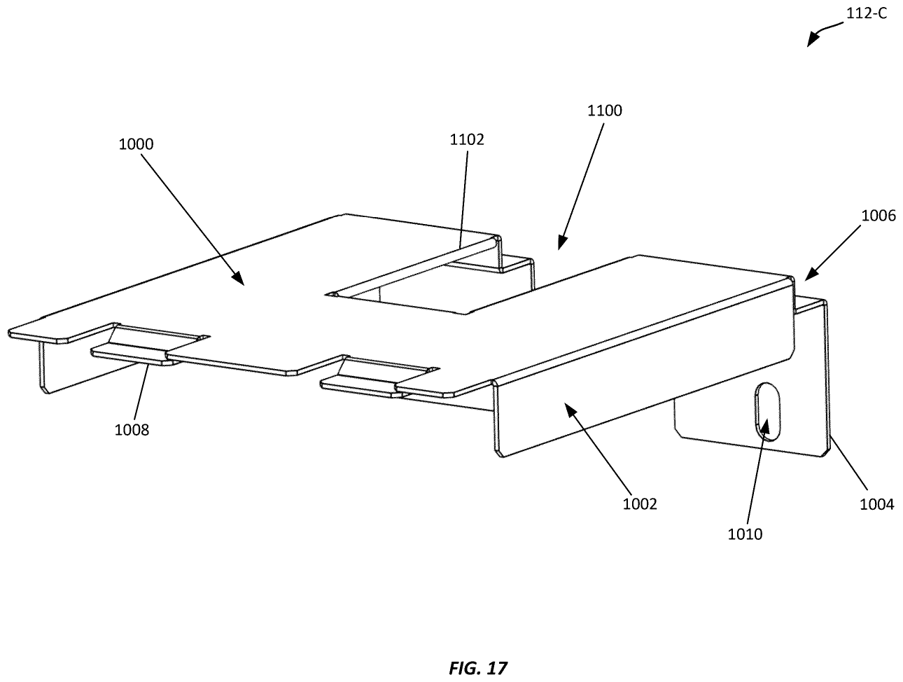

FIG. 16 is a rear perspective view of the third blocking plate 112-C, and FIG. 17 is a front perspective view of the third blocking plate 112-C. The third blocking plate 112-C can be configured to be received in one of the openings 202 in the rack level cage 102. The third blocking plate 112-C can comprise a top plate 1000, side plates 1002, a rear plate 1004, a step 1006 located between and connecting the rear plate 1004 to the top plate 1000, a plurality of depressed tabs 1008, and a plurality of planar tabs 1009. In some embodiments, the planar tabs 1009 can be located in a first plane, which can be the same plane as the top plate, and the depressed tabs 1008 can be located in a second plane below the plane of the planar tabs 1009. In some embodiments, the step 1006 can be configured to engage with a portion of the top panel 114 of the rack level cage 102. In some embodiments, the third blocking plate 112-C can comprise two depressed tabs 1008.

The third blocking plate 112-C, and specifically the top plate 1000 of the third blocking plate 112-C can define a cable opening 1100. The cable opening 1100 can be configured to allow one or more cables to pass through the third blocking plate 112-C from within the rack level cage 102 to outside of the rack level cage 102. In some embodiments, the cable opening 1100 can be defined by one or more cable edges 1102. These cable edges 1102 can be configured to not damage a cable contacting the cable edge 1102. In some embodiments this can include, for example, the cable edge 1102 being rounded, chamfered, folded, having a double thickness, or the like. In the embodiment shown in FIGS. 16 and 17, the cable edges 1102 are doubled, or in other words, the sheet forming the top plate 1000 is folded back onto itself creating a rounded cable edge 1102.

The plurality of depressed tabs 1008 can, in combination with the top plate 1000, receive a portion of the top panel 114. In some embodiments, the portion of the top panel 114 can be received between the depressed tabs 1008 and the top plate 1000 and the third blocking plate 112-C can be moved such that the step 1006 engages with the top plate, at which point one or more fasteners can secure the rear plate 1004 to the rack level cage 102. In some embodiments, the one or more fasteners can secure the rear plate 1004 to the rack level cage 102 via one or more apertures 1010 in the rear plate 1004.

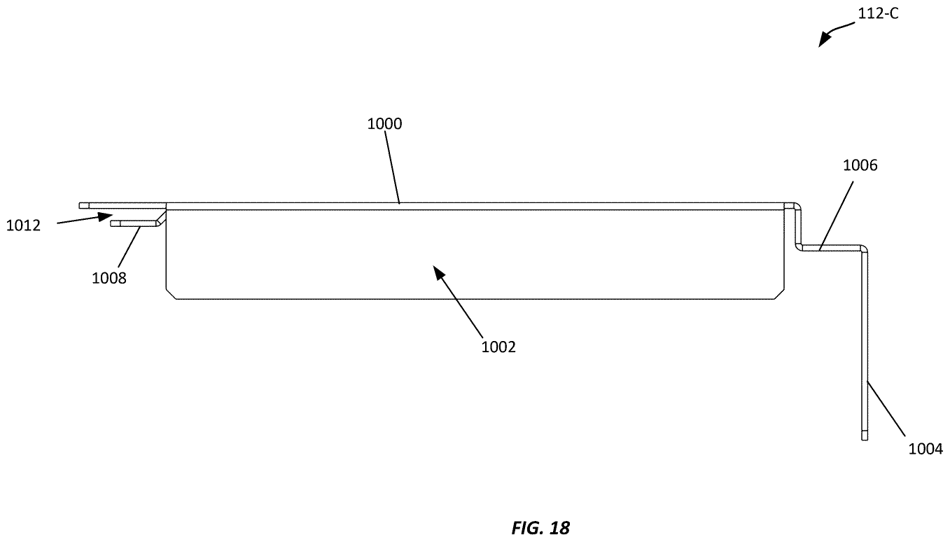

FIG. 18 is a side view of the third blocking plate 112-C. As seen, the depressed tabs 1008 are at a level below the top plate 1000, thereby defining a receiving volume 1012 in which the top panel 114 can be received.

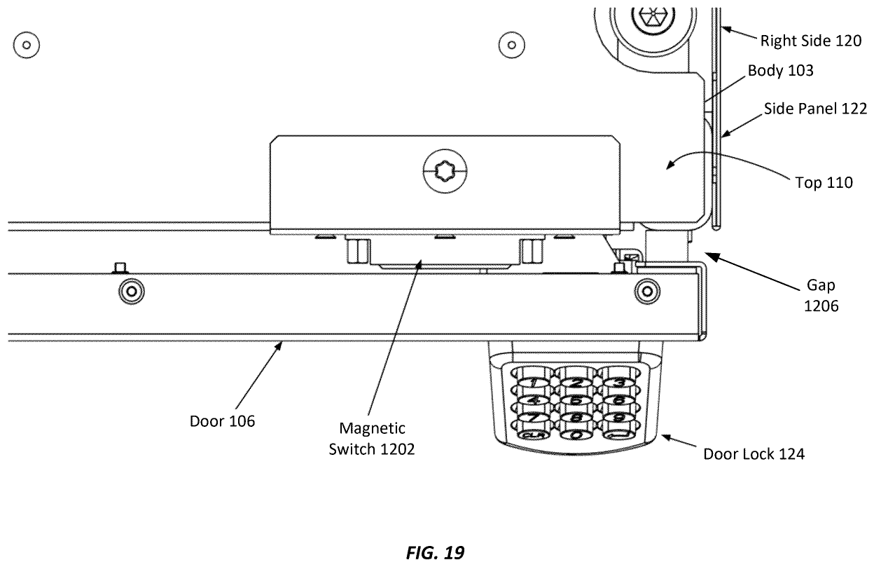

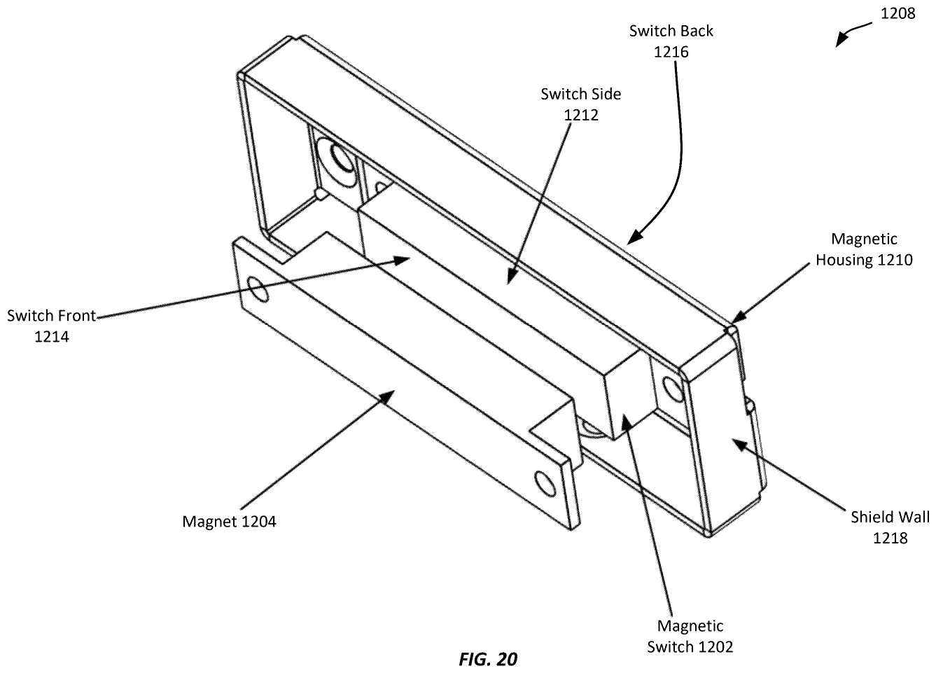

A close-up top view of a portion of the top 110 the rack level cage 102 is shown in FIG. 19. As seen, a magnetic switch 1202 can be positioned, connected to the body 103 of the rack level cage 102 and can, in some embodiments, extend towards a magnet 1204 (shown in FIG. 20) located in and/or connected to the door 106 and/or side panel 122. In some embodiments, a magnetic switch 1202 can be positioned, connected to the door 106 and/or to a panel such as the side panel 122 of the rack level cage 102 and can, in some embodiments, extend towards a magnet 1204 (shown in FIG. 20) located in and/or connected to the rack level cage 102 and/or to the body 103 of the rack level cage 102.

In some embodiments the door 106 can be secured in a closed position via the door lock 124. In some embodiments, one or several magnetic sensors, which can be magnetic switches 1202 can be provided, which sensors 1202 can detect whether the door 106 and/or a panel such as the side panel 122 is in an open position or a closed position. In some embodiments, one or more of these sensors 1202 can be provided with a magnetic shield 1210 to shield the magnetic sensor 1202 from an externally applied magnetic field.

In some embodiments, and as depicted below, the magnetic switch 1202 extends into a gap between the body 103 of the rack cage 102 and the door 106. The magnetic switch 1202 can be manipulated via a magnet 1204 placed close to the magnetic switch 1202 and/or placed into a gap 1206 between the body 103 of the rack level cage 102 and the door 106. In some embodiments, this manipulation can prevent the magnetic switch 1202 from detecting that the door 106 is in the open position and/or that the panel 122 is removed from the body 103.

In some embodiments, and as shown in FIG. 20, a magnetic securement system 1208 can include the switch 1202, the magnet 1204, and a magnetic shield 1210. In some embodiments, the switch 1202 can be partially surrounded by the magnetic housing/shield 1210. The magnetic housing 1210 can comprise a ferrous member positioned around all or portions of the magnetic switch, thereby shielding the magnetic switch from interference from a magnetic field.

The combination of the magnet 1204, the magnetic switch 1202, and the magnetic shield 1210 together create a magnetic securement system, shown below. In some embodiments, the magnetic shield 1210 can be coupled to the rack level cage 102 and specifically to the body 103 of the rack level cage 102. In some embodiments, the magnetic shield 1210 can be positioned to at least partially surround the magnetic switch 1202. In some embodiments, the magnetic shield can be positioned to extend at least partially into the gap 1206 between the body 103 and the door 106.

As seen, the magnetic shield 1210 can extend around some or all sides of the magnetic switch to prevent an external magnet from being placed close to the magnetic switch and to prevent an external magnetic field from affecting the magnetic switch 1202. Thus, in some embodiments, the magnetic shield 1210 can be configured to prevent an external magnetic field from affecting the magnetic switch 1202.

In the embodiment shown below, the magnetic switch has four lateral switch sides 1212, a switch front 1214, also referred to herein as a switch face 1214, and a switch back 1216. The switch back 1216 is mounted on and/or connected to the body 103 of the rack cage 102, and the switch face 1214 is exposed to the magnet 1204 that is mounted on and/or connected to the door 106 such that when the door 106 is closed, the switch face 1214 of the magnetic switch 1202 is positioned proximate to the magnet 1204, and more specifically is positioned relatively more proximate to the magnet 1204 than other surfaces 1212, 1216 of the magnetic switch 1202, and in some embodiments is positioned relatively more proximate to the magnet 1204 than any other surface 1212, 1216 of the magnetic switch 1204.

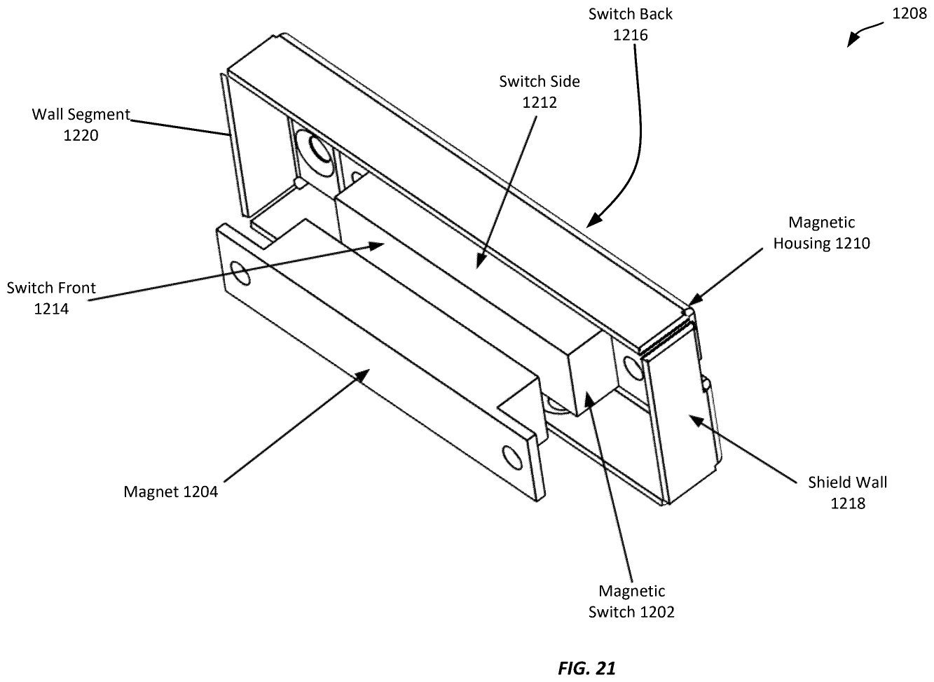

As further seen, the magnetic housing 1210 includes a shield wall 1218 that extends around some or all of the switch sides 1212. The shield wall 1218 can extend around some or all of the switch sides 1212 in a continuous or a non-continuous manner. Thus, in some embodiments, the shield wall 1218 can comprise a single wall that is continuous for its entire length, or can comprise multiple wall segments that together form the shield wall 1218. With reference to the embodiment shown in FIG. 21, for example, the shield wall 1218 can comprise four distinct wall segments 1220 that are not connected at their corners.

The magnetic housing 1210, in some embodiments, does not extend across or over the switch front face 1214 such that the magnetic shield 1210 is not positioned between the magnetic switch 1202 and the magnet 1204 when the door 106 is in the closed position.

In the foregoing specification, aspects of the invention are described with reference to specific aspects thereof, but those skilled in the art will recognize that the invention is not limited thereto. Various features and aspects of the above-described invention may be used individually or jointly. Further, aspects can be utilized in any number of environments and applications beyond those described herein without departing from the broader spirit and scope of the specification. The specification and drawings are, accordingly, to be regarded as illustrative rather than restrictive.

What is claimed is:

1. A physical security system comprising:
a rack cage comprising:
a body defining an internal volume configured to contain at least one server;
a door coupled to the body and moveable between an open position and a closed position, wherein the internal volume of the body is accessible via the door when the door is in the open position; and
a magnetic securement system configured to prevent an external magnetic field from affecting a magnetic switch.

2. The physical security system of claim 1, wherein the magnetic securement system comprises a magnet; a magnetic switch; and a magnetic shield.

3. The physical security system of claim 2, wherein the magnet is coupled to the door, and wherein the magnetic switch is coupled to the body.

4. The physical security system of claim 3, wherein the magnetic shield is coupled to the body and is positioned to at least partially surround the magnetic switch.

5. The physical security system of claim 4, wherein the magnetic shield comprises a ferrous material.

6. The physical security system of claim 5, wherein the magnetic switch comprises a plurality of switch sides and a switch face.

7. The physical security system of claim 6, wherein the switch face is positioned proximate to the magnet when the door is in the closed position.

8. The physical security system of claim 7, wherein the magnetic shield comprises a shield wall.

9. The physical security system of claim 8, wherein the shield wall extends around the switch sides of the magnetic switch.

10. The physical security system of claim 9, wherein the magnetic shield does not extend across the switch face such that the magnetic shield is not positioned between the magnetic switch and the magnet when the door is in the closed position.

11. A physical security system comprising:
a rack cage comprising:
a body defining an internal volume configured to contain at least one server;
a door coupled to the body and moveable between an open position and a closed position, wherein the internal volume of the body is accessible via the door when the door is in the open position; and
a magnetic securement system comprising:
a magnetic switch; and
a magnetic shield extending around a plurality of sides of the magnetic switch.

12. The physical security system of claim 11, wherein the magnetic securement system further comprises a magnet.

13. The physical security system of claim 12, wherein the magnet is coupled to the door, and wherein the magnetic switch is coupled to the body.

14. The physical security system of claim 13, wherein the magnetic shield is coupled to the body and is positioned to extend at least partially into a gap between the body and the door.

15. The physical security system of claim 14, wherein the magnetic shield comprises a ferrous material.

16. The physical security system of claim 15, wherein the magnetic switch comprises a plurality of switch sides and a switch face.

17. The physical security system of claim 16, wherein the switch face is positioned proximate to the magnet when the door is in the closed position.

18. The physical security system of claim 17, wherein the magnetic shield comprises a shield wall.

19. The physical security system of claim 18, wherein the shield wall extends around the switch sides of the magnetic switch.

20. The physical security system of claim 19, wherein the magnetic shield does not extend across the switch face such that the magnetic shield is not positioned between the magnetic switch and the magnet when the door is in the closed position.
